(19) United States
(12) Patent Application Publication
(10) Pub. No.: US 2026/0139360 A1
(43) Pub. Date: May 21, 2026

(54) YTTRIUM-BASED FILM AND METHOD FOR PRODUCING SAME

(71) Applicant: Shincron Co., Ltd., Kanagawa (JP)

(72) Inventors: Kazuhiro SATO, Kanagawa (JP); Kenichi TANABE, Kanagawa (JP); Yoshichika TOKUNO, Kanagawa (JP)

(21) Appl. No.: 18/875,624

(22) PCT Filed: Oct. 6, 2023
(86) PCT No.: PCT/JP2023/036593

§ 371 Date: Jan. 14, 2026

(30) Foreign Application Priority Data
Oct. 11, 2022 (JP) 2022-163428

(51) Int. Cl. C23C 14/28; C23C 14/08; C23C 16/40

(52) U.S. Cl. CPC C23C 14/28; C23C 14/083; C23C 16/405

(57) ABSTRACT

Provided is an yttrium oxide film having Vickers hardness of 900 HV or more, in which the half width determined by X-ray diffractometry of the (222) plane of an yttrium oxide crystal is 0.7° or more, the (222) plane is preferentially oriented in a crystal structure of yttrium oxide, and the diffraction intensity of the (222) plane in X-ray diffractometry is twice or more those of other crystal planes. The yttrium oxide film can be formed on the surface of a component for which corrosion resistance, wear resistance, dust generation resistance, etc. are required, and is formed by any one of a PVD method, a CVD method, or an ALD method, particularly by an ion beam assisted vapor deposition method.

### TECHNICAL FIELD

The present invention relates to an yttrium-based film containing yttrium oxide or yttrium oxyfluoride and a method for producing the same.

### BACKGROUND ART

As this type of yttrium-based film, an yttrium fluoride-based spray film is known, which is obtained by plasma-spraying a spray powder that contains an orthorhombic YF₃ crystal phase and does not contain any other YF₃ crystal phase (see Patent Document 1).

### PRIOR ART DOCUMENT

### Patent Document

Patent Document 1: JP7306490B

### SUMMARY OF INVENTION

### Problems to be solved by Invention

In the above conventional yttrium fluoride-based thermal spray film, however, the Vickers hardness is 560 HV at most, and therefore further improvement in the hardness is required.

A problem to be solved by the present invention is to provide an yttrium-based film excellent in the hardness and a method for producing the same.

### Means for Solving Problems

The present invention solves the above problem by providing an yttrium oxide film having a Vickers hardness of 900 HV or more.

In the above invention, preferably, the half width determined by X-ray diffractometry of the (222) plane of an yttrium oxide crystal is 0.7° or more.

In the above invention, preferably, the (222) plane is preferentially oriented in a crystal structure of yttrium oxide.

In the above invention, preferably, the diffraction intensity of the (222) plane in X-ray diffractometry is twice or more those of other crystal planes.

In the above invention, preferably, the film is formed on the surface of a component for which corrosion resistance, wear resistance, dust generation resistance, etc. are required.

In the above invention, preferably, the above film can be formed by any one of a PVD method, a CVD method, or an ALD method. In particular, it is more preferred to form the above film by an ion beam assisted vapor deposition method.

The present invention also solves the above problem by providing an yttrium oxyfluoride film having a Vickers hardness of 900 HV or more.

In the above invention, preferably, when surface analysis with SEM is performed, the surface of an yttrium oxyfluoride crystal is dominated by a shape in which grains having a grain diameter of 50 nm to 300 nm are formed.

In the above invention, preferably, when surface analysis with SEM is performed, the surface of an yttrium oxyfluoride crystal is dominated by a shape in which grains having a grain diameter of 50 nm to 300 nm are formed and grains having a grain diameter of 5 nm to 20 nm are further formed thereon.

In the above invention, preferably, when cross-sectional analysis with SEM is performed, the cross-section of an yttrium oxyfluoride crystal is not dominated by a fibrous cross-sectional structure having a width of 20 to 50 nm and a length in the thickness direction of 200 um or more, but rather has a structure in which bulk-like columns having a width of 100 nm or more are observed.

In the above invention, preferably, the half width determined by X-ray diffractometry of the (151) plane of an yttrium oxyfluoride crystal is 0.5°or more.

In the above invention, preferably, the (151) plane is preferentially oriented in a crystal structure of yttrium oxyfluoride.

In the above invention, preferably, the diffraction intensity of the (151) plane in X-ray diffractometry is twice or more those of other crystal planes.

In the above invention, preferably, the film is formed on the surface of a component for which at least corrosion resistance, wear resistance, or dust generation resistance is required. Examples of materials for these components include aluminum, quartz, sapphire, and ceramic.

In the above invention, preferably, the above film can be formed by any one of a PVD method, a CVD method, or an ALD method. In particular, it is more preferred to form the above film by an ion beam assisted vapor deposition method.

In the above invention, when the film is formed, periods of film formation and periods of no film formation may be intermittently repeated.

### Effect of Invention

According to the present invention, the film can be obtained with excellent hardness.

### BRIEF DESCRIPTION OF DRAWINGS

FIG. 1 is a diagram illustrating the characteristics of yttrium oxide films according to Example 1 of the present invention and Comparative Example 1.

FIG. 2A is a diagram (part 1) illustrating the characteristics of yttrium oxyfluoride films according to Examples 2 and 3 of the present invention and Comparative Example 2.

FIG. 2B is a diagram (part 2) illustrating the characteristics of yttrium oxyfluoride films according to Examples 2 and 3 of the present invention and Comparative Example 2.

FIG. 3 is a conceptual diagram illustrating the relationship between hardness and crystallinity of yttrium oxyfluoride films.

FIG. 4 is a schematic cross-sectional view illustrating the crystal structure of Example 2 of the present invention (yttrium oxyfluoride film with high hardness).

FIG. 5 is a schematic cross-sectional view illustrating the crystal structure of Comparative Example 2 to the present invention (yttrium oxyfluoride film with low hardness).

### MODE(S) FOR CARRYING OUT THE INVENTION

Hereinafter, one or more embodiments of the present invention will be described with reference to the drawings.

### Yttrium Oxide Film

A hard film of the present invention that has a Vickers hardness of 900 HV or more is an yttrium oxide film, in which the half width determined by X-ray diffractometry of the (222) plane of an yttrium oxide crystal is 0.7° or more, the (222) plane is preferentially oriented in a crystal structure of yttrium oxide, and the diffraction intensity of the (222) plane in X-ray diffractometry is twice or more those of other crystal planes. The yttrium oxide film can be formed on the surface of a component for which corrosion resistance, wear resistance, dust generation resistance, etc. are required, and the film can be formed by any one of a PVD method, a CVD method, or an ALD method.

Additionally or alternatively, a hard film of the present invention that has a Vickers hardness of 900 HV or more is an yttrium oxyfluoride film, in which, when surface analysis with SEM is performed, the surface of an yttrium oxyfluoride crystal is dominated by a shape in which grains having a grain diameter of 50 nm to 300 nm are formed and grains having a grain diameter of 5 nm to 20 nm are further formed thereon, while when cross-sectional analysis with SEM is performed, the cross-section of an yttrium oxyfluoride crystal is not dominated by a fibrous cross-sectional structure having a width of 20 to 50 nm and a length in the thickness direction of 200 nm or more, but rather has a structure in which bulk-like columns having a grain diameter of 100 nm or more are observed, and the half width determined by X-ray diffractometry of the (151) plane of an yttrium oxyfluoride crystal is 0.5° or more. The (151) plane is preferentially oriented in a crystal structure of yttrium oxyfluoride, and the diffraction intensity of the (151) plane in X-ray diffractometry is twice or more those of other crystal planes. The yttrium oxyfluoride film can be formed on the surface of a component for which corrosion resistance, wear resistance, dust generation resistance, etc. are required, and the film can be formed by any one of a PVD method, a CVD method, or an ALD method.

### EXAMPLES

The present invention will be described in more detail below with reference to Examples and Comparative Examples. Note, however, that the present invention is not limited to the conditions and results of these Examples.

### Example 1 and Comparative Example 1 (Yttrium Oxide Films)

Using an ion beam assisted vacuum vapor deposition device (EPD available from SHINCRON CO., LTD.) together with yttrium oxide Y₂O₃ as the vapor deposition source, the surface of a sapphire substrate was irradiated/unirradiated with an ion beam by setting a film formation rate within a range of 0 to 10 angstroms/second (both ends exclusive) to form a film. The films obtained by combining different film formation conditions were designated as Example 1 and Comparative Example 1.

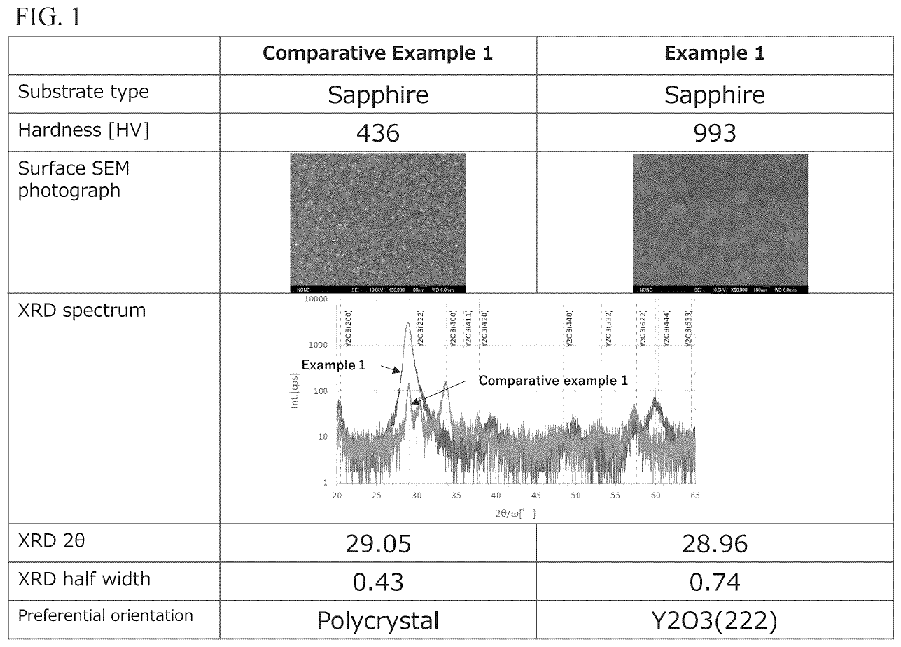

For the film obtained in each of Example 1 and Comparative Example 1, the Vickers hardness was measured using a Vickers hardness tester (available from Bruker), SEM photographs of the film surface were taken using a scanning electron microscope (available from JEOL Ltd.), and the crystallinity of the film was confirmed using an X-ray diffractometer (available from Rigaku Corporation). FIG. 1 illustrates the characteristics of the yttrium oxide films according to Example 1 and Comparative Example 1. In FIG. 1, “Hardness HV” refers to the Vickers hardness, “Surface SEM photograph” refers to a photograph of the film surface taken with the scanning electron microscope, “XRD spectrum” refers to the diffraction intensity-diffraction angle taken with the X-ray diffractometer, “XRD 2θ” refers to the diffraction angle of X-ray diffraction (θ is the Bragg angle), and “XRD half width” refers to the half width at a diffraction angle 2θ.

Comparing the hardness values illustrated in FIG. 1, the hardness of Example 1 is 993 HV, which is higher than that of Comparative Example 1. In addition, comparing the SEM photographs illustrated in FIG. 1, the surface of Example 1 is smoother than that of Comparative Example 1. Furthermore, comparing the X-ray diffraction spectra, diffraction peaks, and half widths of the diffraction peaks of FIG. 1, it has been confirmed that while the (222) plane of the yttrium oxide crystal has a diffraction peak at a diffraction angle of 2θ=29°, in Example 1, the diffraction peak of the (222) plane at a diffraction angle of 2θ≈29° is twice or more as strong as the diffraction intensity of other crystal planes, and the half width of the diffraction peak of the (222) plane is also large at 0.7° or more. From these results, it has been confirmed that the (222) plane is preferentially oriented in the crystal structure of the yttrium oxide constituting the film of Example 1.

### Examples 2 and 3 and Comparative Example 2 (Yttrium oxyfluoride films)

Using an ion beam assisted vacuum vapor deposition device (MIC available from SHINCRON CO., LTD.) together with yttrium oxide Y₂O₃ and yttrium fluoride YF₃ as two vapor deposition sources, the surface of a quartz substrate was irradiated/unirradiated with ion beams by setting a total film formation rate of yttrium oxide Y₂O₃ and yttrium fluoride YF₃ within a range of 0 to 10 angstroms/second (both ends exclusive) and setting a film formation rate ratio of yttrium oxide Y₂O₃/yttrium fluoride YF3 within a range of 10% to 90% (both ends exclusive) to form a film. The films obtained under different film formation conditions were designated as Examples 2 and 3 and Comparative Example 2. Note that Example 3 is an example in which the film was formed by intermittently repeating periods of film formation and periods of no film formation in order to prevent the substrate temperature from overheating above a predetermined temperature during the film formation.

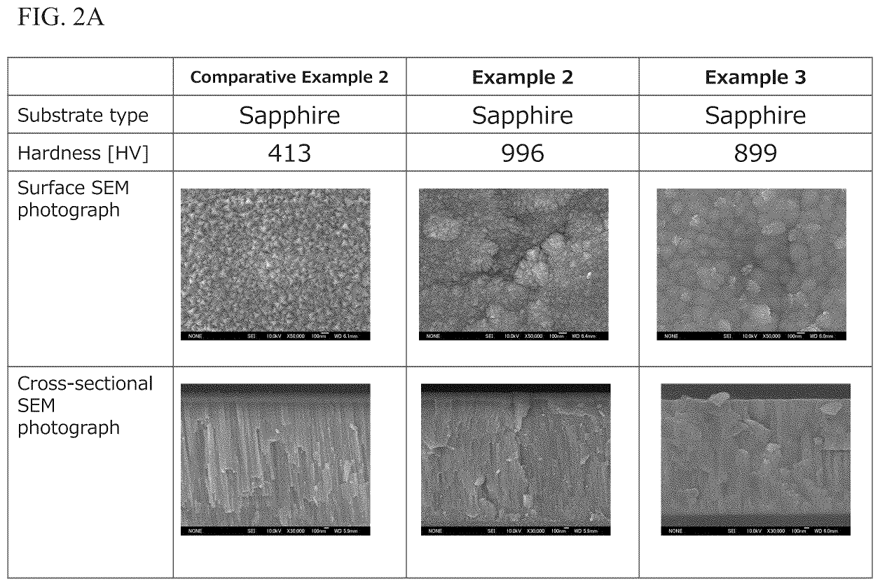

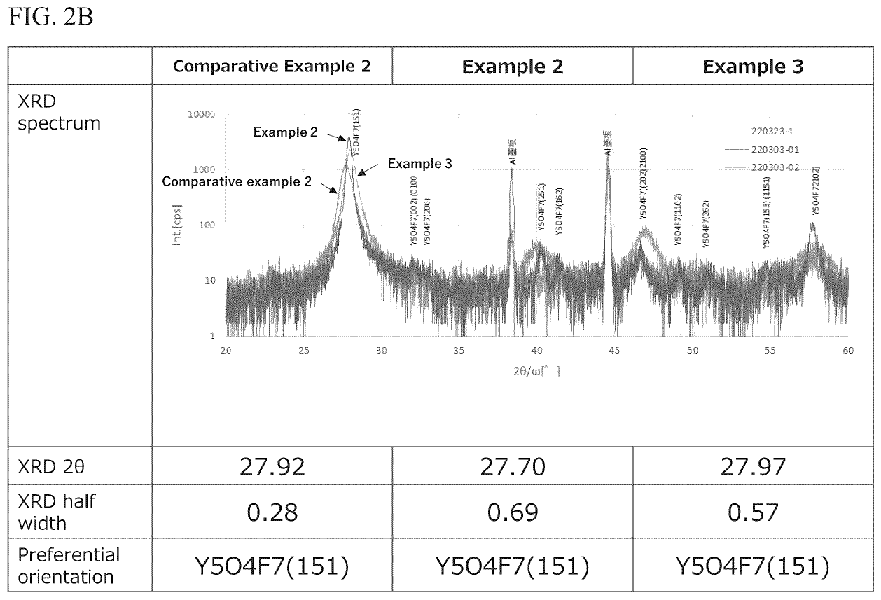

For the film obtained in each of Examples 2 and 3 and Comparative Example 2, the Vickers hardness was measured using a Vickers hardness tester (available from Bruker), SEM photographs of the film surface were taken using a scanning electron microscope (available from JEOL Ltd.), and the crystallinity of the film was confirmed using an X-ray diffractometer (available from Rigaku Corporation). FIGS. 2A and 2B illustrate the characteristics of the yttrium oxyfluoride films according to Examples 2 and 3 and Comparative Example 2. In FIG. 2A, “Hardness HV” refers to the Vickers hardness, “Surface SEM photograph” refers to a photograph of the film surface taken with the scanning electron microscope, and “Cross-sectional SEM photograph” refers to a photograph of the film cross-section taken with the scanning electron microscope. In FIG. 2B, “XRD spectrum” refers to the diffraction intensity-diffraction angle taken with the X-ray diffractometer, “XRD 2θ” refers to the diffraction angle of X-ray diffraction (θ is the Bragg angle), and “XRD half width” refers to the half width at a diffraction angle 2θ.

Comparing the hardness values illustrated in FIG. 2A, the hardness of Example 2 is 996 HV, and the hardness of Example 3 is 899 HV, so the hardness of both Examples 2 and 3 is higher than that of Comparative Example 2. In addition, comparing the surface SEM photographs illustrated in FIG. 2A, the surfaces of Examples 2 and 3 are both smoother than that of Comparative Example 2. Also, comparing the cross-sectional SEM photographs illustrated in FIG. 2A, the cross-section of the film of Comparative Example 2 has a fibrous cross-sectional structure with a width of 20 to 50 nm and a length in the thickness direction of 200 nm or more, whereas the cross-sections of the films of Examples 2 and 3 are not such a fibrous cross-section, but rather have a cross-sectional structure in which grains having a grain diameter of 50 nm to 300 nm are formed and grains having a grain diameter of 5 nm to 20 nm are further formed thereon.

Furthermore, comparing the X-ray diffraction spectra, diffraction peaks, and half widths of the diffraction peaks of FIG. 2B, while the (151) plane of the yttrium oxyfluoride crystal has a diffraction peak at a diffraction angle of 2θ=28°, the diffraction intensity of the (151) plane at a diffraction angle of 2θ˜28° is twice or more as strong as the diffraction intensity of other crystal planes, but the half width of the diffraction peak of the (151) plane in Example 2 is 0.69°, and the half width of the diffraction peak of the (151) plane in Example 3 is 0.57°, both of which are larger than the half width 0.28° of the diffraction peak of the (151) plane in Comparative Example 2.

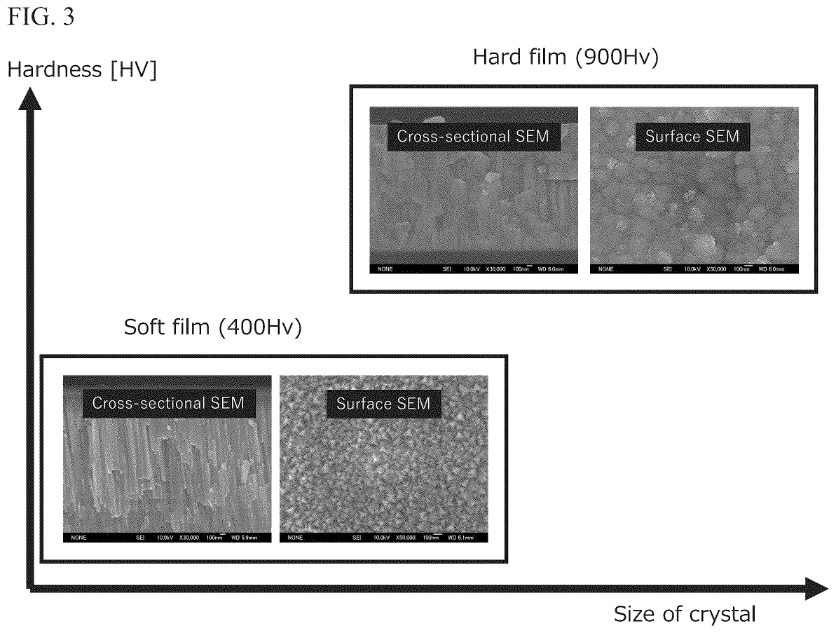

FIG. 3 is a conceptual diagram illustrating the relationship between the hardness of films and the size of crystals. There is a correlation between the crystal structure observed with SEM and the hardness of the film, and as illustrated in FIG. 3, the larger the crystals of the film, the higher the hardness. In general, it can be said that a film with high hardness is excellent in the corrosion resistance and wear resistance. Moreover, a film with high hardness has a smoother surface than a film with low hardness. In general, it can be said that the smoother the surface and the higher the hardness, the less likely the film is to be scraped off, and therefore the more excellent the dust generation resistance.

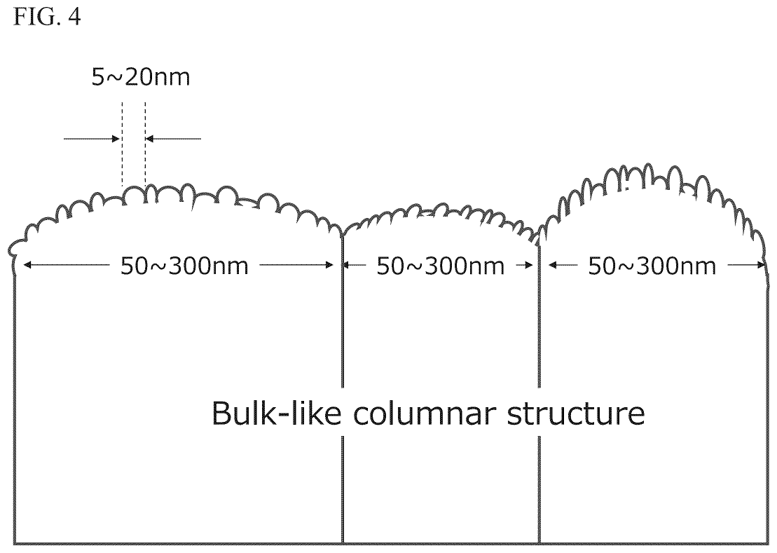

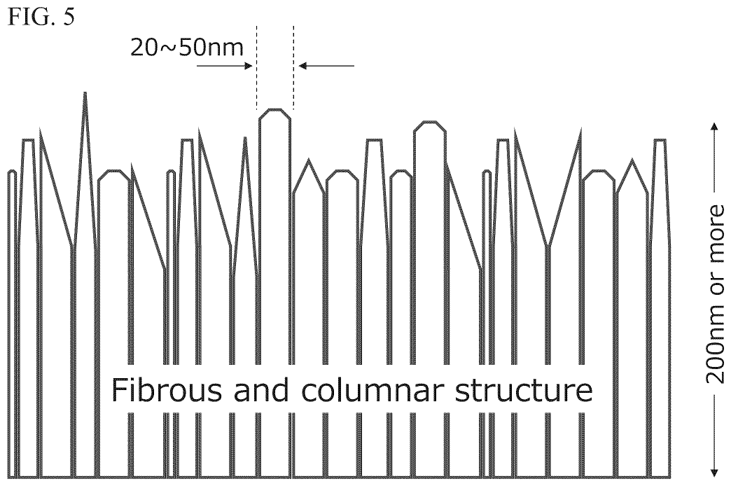

FIGS. 4 and 5 are schematic cross-sectional views of films each illustrating the relationship between the hardness and the crystal structure of the film, and FIG. 4 represents Example 2 while FIG. 5 represents Comparative Example 2. As illustrated in FIG. 4, the yttrium oxyfluoride film having a high hardness of 900 HV or more is dominated by a film crystal structure in which grains of 5 nm to 20 nm are further stacked on the top of a bulk-like columnar structure with a grain diameter of 50 nm to 300 nm. In contrast, as illustrated in FIG. 5, the yttrium oxyfluoride film having a low hardness of 400 HV or less is dominated by a fibrous cross-sectional structure with a width of 20 to 50 nm and a length in the thickness direction of 200 nm or more.

From the viewpoint of the corrosion resistance of the film, it is preferred to have fewer crystal grain boundaries, that is, fewer columnar crystal interfaces, in the film. This is because there is a concern that corrosive gases or the like may erode through the interstices of the crystal grain boundaries and reach the substrate or the like. Moreover, from the viewpoint of wear resistance or dust generation resistance, it is preferred that the surface shape of the film be smooth. This is because if fine needle-like irregularities are formed on the surface, they are easily worn away and may become a source of dust generation. When the films of FIGS. 4 and 5 are evaluated from these viewpoints, the film of Example 2 illustrated in FIG. 4 exhibits film properties superior to those of Comparative Example 2 illustrated in FIG. 5 in terms of the crystal structure, such as corrosion resistance, wear resistance, and dust generation resistance.

1-18. (canceled)

19. A method for producing an yttrium oxyfluoride film having a Vickers hardness of 900 HV or more, comprising:
forming the yttrium oxyfluoride film by a PVD method, a CVD method, an ALD method, or an ion beam assisted vapor deposition method; and
when forming the yttrium oxyfluoride film, intermittently repeating periods of film formation and periods of no film formation.

20. The method for producing an yttrium oxyfluoride film according to claim 19, wherein, when surface analysis with SEM is performed for the yttrium oxyfluoride film, a surface of an yttrium oxyfluoride crystal is dominated by a shape in which grains having a grain diameter of 50 nm to 300 nm are formed.

21. The method for producing an yttrium oxyfluoride film according to claim 19, wherein, when surface analysis with SEM is performed for the yttrium oxyfluoride film, a surface of an yttrium oxyfluoride crystal is dominated by a shape in which grains having a grain diameter of 50 nm to 300 nm are formed and grains having a grain diameter of 5 nm to 20 nm are further formed thereon.

22. The method for producing an yttrium oxyfluoride film according to claim 19, wherein, when cross-sectional analysis with SEM is performed for the yttrium oxyfluoride film, a cross-section of an yttrium oxyfluoride crystal is not dominated by a fibrous cross-sectional structure having a width of 20 to 50 nm and a length in a thickness direction of 200 nm or more, but rather has a structure in which bulk-like columns having a width of 100 nm or more are observed.

23. The method for producing an yttrium oxyfluoride film according to claim 19, wherein a half width determined by X-ray diffractometry of a (151) plane of an yttrium oxyfluoride crytal of the yttrium film is 0.5° or more.

24. The method for producing an yttrium oxyfluoride film according to claim 19, wherein a (151) plane is preferentially oriented in a crystal structure of yttrium oxyfluoride of the yttrium oxyfluoride film.

25. The method for producing an yttrium oxyfluoride film according to claim 24, wherein a diffraction intensity of the (151) plane in X-ray diffractometry is twice or more those of other crystal planes.

26. The method for producing an yttrium oxyfluoride film according to claim 19, formed on a surface of a component for which at least corrosion resistance, wear resistance, or dust generation resistance is required.
